(19) United States
(12) Patent Application Publication
(10) Pub. No.: US 2011/0169584 A1
(43) Pub. Date: Jul. 14, 2011

(54) PIEZOELECTRIC VIBRATOR MANUFACTURING METHOD, OSCILLATOR, ELECTRONIC DEVICE, AND ATOMIC TIMEPIECE

(76) Inventor: Junya Fukuda, Chiba-shi (JP)

(21) Appl. No.: 12/984,198

(22) Filed: Jan. 4, 2011

(30) Foreign Application Priority Data
Jan. 8, 2010 (JP) 2010-003352

(51) Int. Cl. H01L 41/22; H01L 41/04; H03B 5/32

(52) U.S. Cl. 331/158; 29/25.35; 310/312

(57) ABSTRACT

To provide a piezoelectric vibrator manufacturing method that curbs a dispersion of a bonding film at a time of a gettering step and with which good electrical characteristics can be obtained, and an oscillator, electronic device, and atomic timepiece, in which is mounted a piezoelectric vibrator with which good electrical characteristics can be obtained. A manufacturing method includes a gettering step whereby a getter material is irradiated with a first laser penetrating a base substrate from the outer side of the base substrate, activating the getter material so that it adsorbs gas existing inside a cavity, and a frequency adjustment step whereby a weight metal film formed at leading ends of vibrating arms of a piezoelectric vibrating piece is irradiated with a second laser penetrating the base substrate from the outer side of the base substrate, thus adjusting the frequency of the piezoelectric vibrating piece, wherein the intensity of the first laser in the gettering step is weaker than the intensity of the second laser in the frequency adjustment step.

### RELATED APPLICATIONS

This application claims priority under 35 U.S.C. §119 to Japanese Patent Application No. 2010-003352 filed on Jan. 8, 2010, the entire content of which is hereby incorporated by reference.

### BACKGROUND OF THE INVENTION

1. Field of the Invention

The present invention relates to a piezoelectric vibrator manufacturing method, a piezoelectric vibrator, an oscillator, an electronic device, and an atomic timepiece.

2. Related Art

In recent years, a piezoelectric vibrator utilizing a piezoelectric vibrating piece formed from a piezoelectric material such as quartz has been used in portable telephones and portable information terminal instruments as a time source, a control signal timing source, a reference signal source, and the like. A tuning fork-shaped piezoelectric vibrating piece including a pair of vibrating arms is employed as the piezoelectric vibrating piece.

As this kind of piezoelectric vibrator, a surface mount type (SMD) piezoelectric vibrator is known.

As the surface mount type piezoelectric vibrator, one is proposed wherein a package is formed of a base substrate and a lid substrate, and a piezoelectric vibrating piece is housed in a cavity formed inside the package. The base substrate and lid substrate, a bonding film being disposed between the two, are bonded by means of an anodic bonding. The bonding film is formed from a metal such as aluminum (Al) or chromium (Cr), a semiconductor such as silicon (Si), or the like, and is provided on the surface of the base substrate that bonds to the lid substrate, or on the surface of the lid substrate that bonds to the base substrate. Herein, as the lid substrate has no electrode, when forming the bonding film on the lid substrate, there is no need for a step of masking the electrode. For this reason, because of a demand for a simplification of the manufacturing process and a reduction in the manufacturing cost, it is often the case recently that the bonding film is formed over the whole of the surface of the lid substrate that bonds to the base substrate.

However, it is desirable that an equivalent resistance value (an effective resistance value, Re) of the piezoelectric vibrator is kept low. As a piezoelectric vibrator with a low equivalent resistance value can cause the piezoelectric vibrating piece to vibrate with low power, it is an energy-efficient piezoelectric vibrator. As one common method of suppressing the equivalent resistance value, a method is known whereby the inside of the cavity in which the piezoelectric vibrating piece is sealed is brought close to a vacuum, thus reducing a serial resonance resistance value (R1), which is in a proportional relationship to the equivalent resistance value.

As a method of bringing the inside of the cavity close to a vacuum, there is known a method including a gettering step whereby a getter material formed from Al, Cr, or the like, is sealed on the base substrate inside the cavity and irradiated from the exterior with a laser, thus activating the getter material (refer to JP-A-2003-142976). According to this method, as it is possible to absorb oxygen emitted at the time of the anodic bonding with the getter material which is in an activated condition, it is possible to bring the inside of the cavity close to a vacuum.

Also, after the gettering step, a fine adjustment of the frequency of the piezoelectric vibrating piece (a frequency adjustment step) is carried out by a weight metal film formed on the leading end portions of the vibrating arms being irradiated with a laser, trimming the weight metal film. By carrying out the frequency adjustment step, it is possible to keep the frequency of the piezoelectric vibrating piece within a nominal frequency range.

As the getter material and weight metal film are formed near to each other, it is common to use the same laser emitting device in the gettering step as in the frequency adjustment step, and irradiate the getter material with the laser at the same laser intensity as that in the frequency adjustment step. By sharing the laser emitting device between the gettering step and frequency adjustment step, a rise in cost of manufacturing equipment is curbed.

However, in the gettering step, when irradiating the getter material formed on the inner side of the base substrate from the outer side of the base substrate, it may happen that the laser passes through the getter material, and reaches the lid substrate. Then, when the bonding film is formed on the inner side of the lid substrate, as heretofore described, the bonding film is irradiated with the laser, and the bonding film is dispersed.

Herein, when the bonding film is formed from a metal having a gettering effect, such as Al, the bonding film of Al or the like dispersed by the laser irradiation is activated, and adsorbs peripheral gas. Then, as it is possible to bring the inside of the cavity still nearer to a vacuum, it is possible to improve the equivalent resistance value of the piezoelectric vibrator. On the other hand, however, there is a danger of one portion of the dispersed bonding film adhering to the vibrating arms of the piezoelectric vibrating piece. Then, when the bonding film adheres to the vibrating arms of the piezoelectric vibrating piece, the equivalent resistance value of the piezoelectric vibrator rises. At this time, when the deterioration of the equivalent resistance value due to the adhering of the bonding film is greater than the improvement of the equivalent resistance value due to the gettering effect, there is an overall rise in the equivalent resistance value of the piezoelectric vibrator, meaning that as a result the efficiency of the piezoelectric vibrator deteriorates.

As the bonding film is exposed to the exterior at a bonding portion of the two substrates, there is a problem in that the bonding film formed from a metal such as Al corrodes, and it becomes difficult to maintain the air-tightness of the package. Therefore, in order to prevent the corrosion of the bonding film, and further improve the sealing function of the bonding film, Si may be used for the bonding film instead of a metal such as Al. Herein, when the bonding film is irradiated with the laser that has passed through the getter material, as previously described, the Si is dispersed. However, unlike a metal such as Al, Si has no gettering effect. Then, when one portion of the dispersed Si adheres to the vibrating arms of the piezoelectric vibrating piece, the equivalent resistance value of the piezoelectric vibrator rises, and the efficiency of the piezoelectric vibrator deteriorates.

### SUMMARY OF THE INVENTION

Therefore, the invention has an object of providing a piezoelectric vibrator manufacturing method that curbs a dispersion of a bonding film at a time of a gettering step and with which good electrical characteristics can be obtained, and an oscillator, electronic device, and atomic timepiece, in which is mounted a piezoelectric vibrator with which good electrical characteristics can be obtained.

In order to achieve the object, a piezoelectric vibrator manufacturing method of one aspect of the invention is a manufacturing method of a piezoelectric vibrator including a base substrate and a lid substrate bonded to each other, a bonding film formed over the whole of the surface of the lid substrate that bonds to the base substrate, a cavity formed between the base substrate and the lid substrate, a piezoelectric vibrating piece sealed inside the cavity and mounted on the base substrate, and a getter material sealed inside the cavity and formed on the base substrate, the manufacturing method including a gettering step of the getter material being irradiated with a first laser penetrating the base substrate from the outer side of the base substrate, activating the getter material so that it adsorbs gas existing inside the cavity, and a frequency adjustment step of a weight metal film formed at leading ends of vibrating arms of the piezoelectric vibrating piece being irradiated with a second laser penetrating the base substrate from the outer side of the base substrate, thus adjusting the frequency of the piezoelectric vibrating piece, wherein the intensity of the first laser in the gettering step is weaker than the intensity of the second laser in the frequency adjustment step.

According to the aspect of the invention, in the gettering step, as the intensity of the first laser is weaker than the intensity of the second laser, even in the event that the first laser penetrates the getter material and reaches the bonding film formed on the lid substrate, the amount of the bonding film dispersing is small. Because of this, as it is possible to reduce the amount of the bonding film adhering to the vibrating arms of the piezoelectric vibrating piece, it is possible to curb the rise of the equivalent resistance value of the piezoelectric vibrator. Consequently, it is possible to curb the deterioration of the efficiency of the piezoelectric vibrator, and it is possible to manufacture a piezoelectric vibrator with which good electrical characteristics can be obtained.

Also, it is preferable that the first laser does not penetrate the getter material.

According to the aspect of the invention, as the first laser does not penetrate the getter material in the gettering step, the first laser does not reach the bonding film formed on the lid substrate, nor is the bonding film dispersed. Because of this, as the bonding film does not adhere to the vibrating arms of the piezoelectric vibrating piece, it is possible to reliably curb the rise of the equivalent resistance value of the piezoelectric vibrator. Consequently, it is possible to reliably curb the deterioration of the efficiency of the piezoelectric vibrator, and it is possible to manufacture a piezoelectric vibrator with which good electrical characteristics can be obtained.

Also, it is preferable to emit the first laser and second laser by using the same laser emitting device in the gettering step and the frequency adjustment step, and adjusting the laser intensity.

According to the aspect of the invention, the first laser in the gettering step and the second laser in the frequency adjustment step are emitted by using the same laser emitting device, and adjusting the laser intensity. Because of this, as it is possible to share the laser emitting device between the gettering step and the frequency adjustment step, it is possible to curb a rise in the manufacturing cost of the piezoelectric vibrator.

Also, it is preferable that the bonding film is formed from Si.

According to the aspect of the invention, as the bonding film is formed from Si, it has superior corrosion resistance compared with a case in which the bonding film is formed from a metal such as Al. Consequently, it is possible to further improve the sealing function of the bonding film. However, as Si has no gettering effect, as previously described, when the Si is dispersed by the first laser and adheres to the piezoelectric vibrating piece, the equivalent resistance value of the piezoelectric vibrator rises. In response to this, according to the aspect of the invention, either the first laser does not reach the bonding film, or the laser intensity is weak even in the event that the first laser reaches the bonding film, meaning that it is possible to curb the dispersion of the Si bonding film. Because of this, as it is possible to reduce the amount of the Si bonding film adhering to the vibrating arms of the piezoelectric vibrating piece, it is possible to curb the rise of the equivalent resistance value of the piezoelectric vibrator.

With an oscillator of another aspect of the invention, the piezoelectric vibrator manufactured using the manufacturing method is electrically connected to an integrated circuit as a resonator.

With an electronic device of another aspect of the invention, the piezoelectric vibrator manufactured using the manufacturing method is electrically connected to a timing unit.

With an atomic timepiece of another aspect of the invention, the piezoelectric vibrator manufactured using the manufacturing method is electrically connected to a filter unit.

According to the oscillator, electronic device, and atomic timepiece according to the aspects of the invention, as they include a piezoelectric vibrator manufactured using a manufacturing method with which good electrical characteristics can be obtained, it is possible to provide an oscillator, electronic device, and atomic timepiece with good performance.

According to the aspects of the invention, as the intensity of the first laser is weaker than that of the second laser in the gettering step, even in the event that the first laser penetrates the getter material and reaches the bonding film formed on the lid substrate, the amount of the bonding film dispersing is small. Because of this, as it is possible to reduce the amount of the bonding film adhering to the vibrating arms of the piezoelectric vibrating piece, it is possible to curb the rise of the equivalent resistance value of the piezoelectric vibrator. Consequently, it is possible to curb the deterioration of the efficiency of the piezoelectric vibrator, and it is possible to manufacture a piezoelectric vibrator with which good electrical characteristics can be obtained.

### BRIEF DESCRIPTION OF THE DRAWINGS

FIG. 1 is an external perspective view showing a piezoelectric vibrator;

FIG. 2, being an internal configuration diagram of the piezoelectric vibrator shown in FIG. 1, is a plan view thereof in a condition in which a lid substrate is removed;

FIG. 3 is a sectional view along a line A-A of FIG. 2;

FIG. 4 is an exploded perspective view of the piezoelectric vibrator shown in FIG. 1;

FIG. 5 is a plan view of a piezoelectric vibrating piece;

FIG. 6 is a bottom view of the piezoelectric vibrating piece;

FIG. 7 is a sectional view along a line B-B of FIG. 5;

FIG. 8 is a flowchart of a manufacturing method of the piezoelectric vibrator;

FIG. 9 is an exploded perspective view of a wafer body;

FIG. 10 is an illustration of a gettering step and a frequency adjustment step;

FIG. 11 is a configuration diagram showing one embodiment of an oscillator;

FIG. 12 is a configuration diagram showing one embodiment of an electronic device; and

FIG. 13 is a configuration diagram showing one embodiment of an atomic timepiece.

### DETAILED DESCRIPTION OF THE PREFERRED EMBODIMENTS

Hereafter, a description will be given, referring to the drawings, of a piezoelectric vibrator according to an embodiment of the invention.

Hereafter, the description will be given taking a surface of a base substrate bonded to a lid substrate as a first surface U, and the opposite surface as a second surface L.

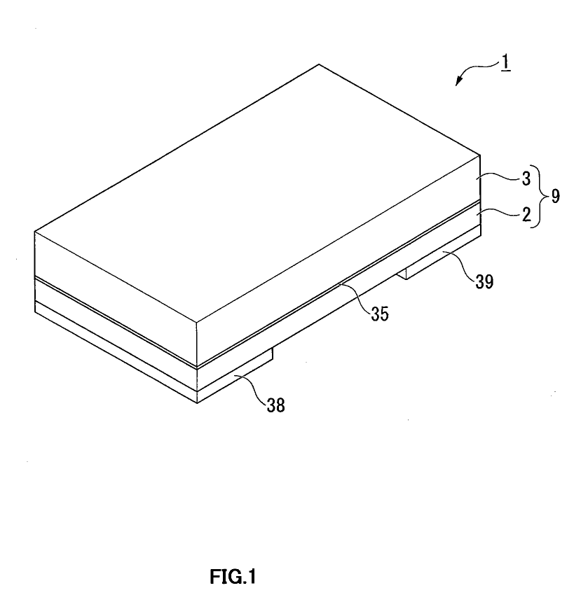

FIG. 1 is an external perspective view of the piezoelectric vibrator in the embodiment.

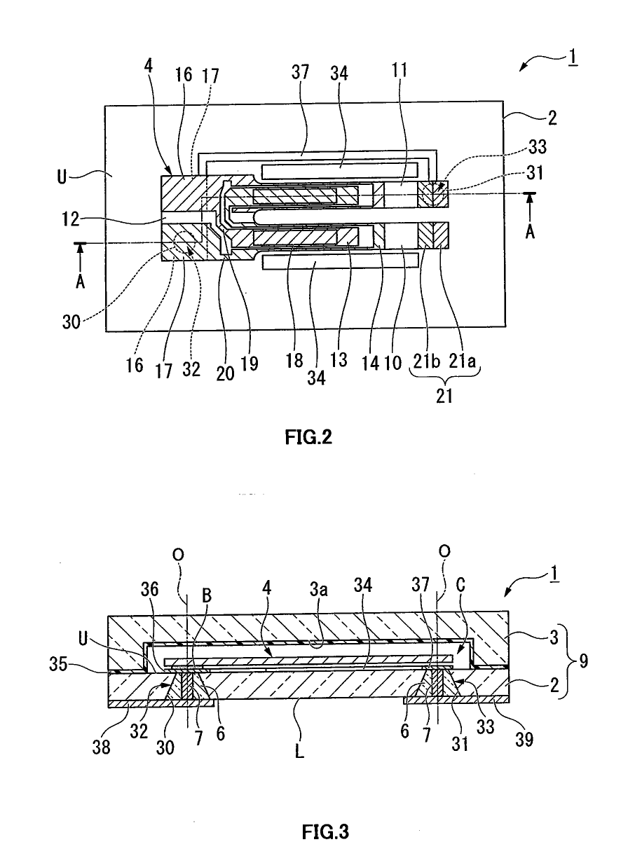

FIG. 2, being an internal configuration diagram of the piezoelectric vibrator, is a plan view thereof in a condition in which the lid substrate is removed.

FIG. 3 is a sectional view along a line A-A of FIG. 2.

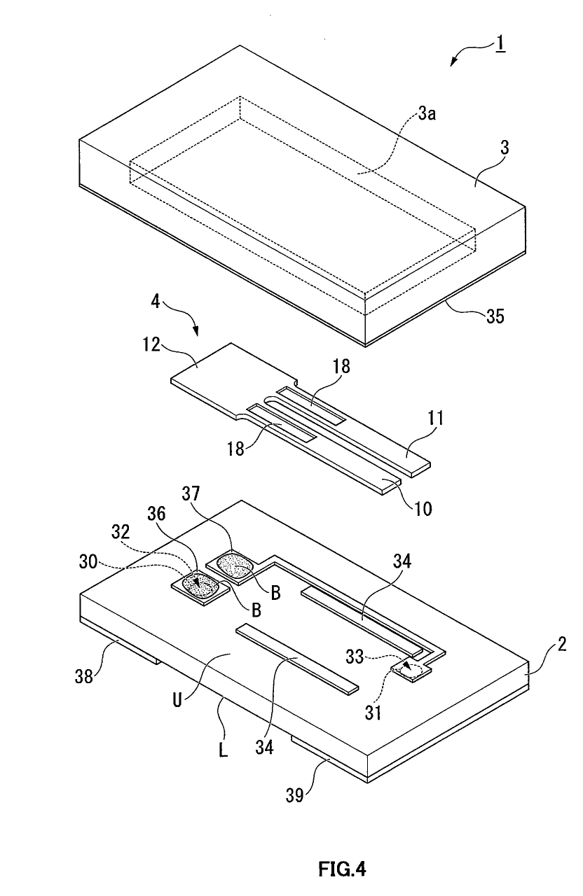

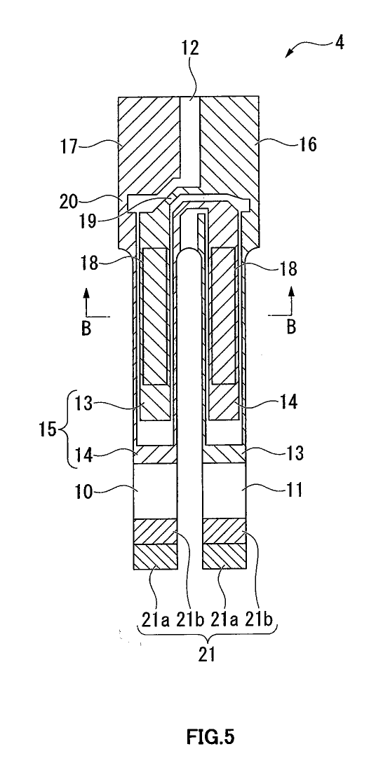

FIG. 4 is an exploded perspective view of the piezoelectric vibrator shown in FIG. 1.

In FIG. 4, in order to make the drawing easier to understand, a depiction of an exciting electrode 15, drawing electrodes 19 and 20, mount electrodes 16 and 17, and a weight metal film 21, to be described hereafter, is omitted.

As shown in FIGS. 1 to 4, a piezoelectric vibrator 1 of the embodiment is a surface mount type piezoelectric vibrator 1 including a package 9, wherein a base substrate 2 and lid substrate 3 are anodically bonded via a bonding film 35, and a piezoelectric vibrating piece 4 housed in a cavity C of the package 9.

### Piezoelectric Vibrating Piece

FIG. 5 is a plan view of the piezoelectric vibrating piece.

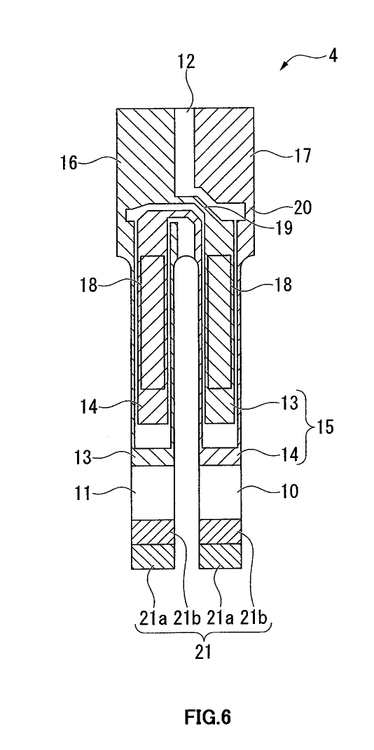

FIG. 6 is a bottom view of the piezoelectric vibrating piece.

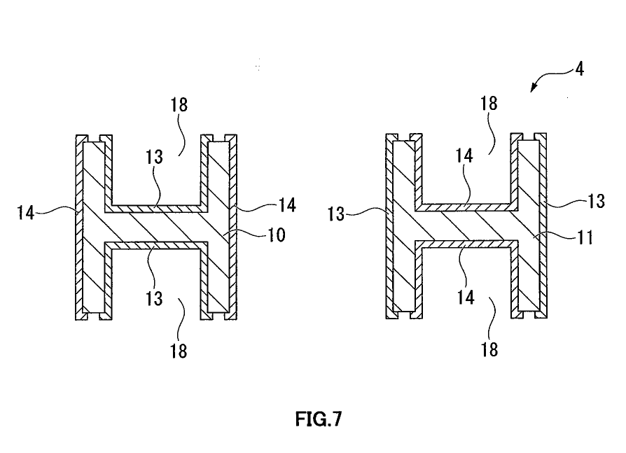

FIG. 7 is a sectional view along a line B-B of FIG. 5.

As shown in FIGS. 5 to 7, the piezoelectric vibrating piece 4, being a tuning-fork shaped vibrating piece formed from a piezoelectric material such as quartz, lithium tantalate, or lithium niobate, vibrates when a predetermined voltage is applied. The piezoelectric vibrating piece 4 includes a pair of vibrating arms 10 and 11 disposed in parallel, a base portion 12 that integrally fixes the base end sides of the pair of vibrating arms 10 and 11, and a groove 18 formed in the main surface of both of the pair of vibrating arms 10 and 11. The grooves 18 are formed from the base end side to around the approximate center of the vibrating arms 10 and 11 in the longitudinal direction of the vibrating arms 10 and 11.

The piezoelectric vibrating piece 4 includes the exciting electrode 15 configured of a first exciting electrode 13 and second exciting electrode 14, formed on external surfaces of the pair of vibrating arms 10 and 11, that causes the pair of vibrating arms 10 and 11 to vibrate, and the mount electrodes 16 and 17 electrically connected to the first exciting electrode 13 and second exciting electrode 14. The exciting electrode 15, mount electrodes 16 and 17, and drawing electrodes 19 and 20 are formed of a film of an electrically-conductive material such as chromium (Cr), nickel (Ni), aluminum (Al), or titanium (Ti).

The exciting electrode 15 is an electrode that causes the pair of vibrating arms 10 and 11 to vibrate at a predetermined resonance frequency in a direction approaching or moving away from each other. The first exciting electrode 13 and second exciting electrode 14 configuring the exciting electrode 15 are formed by patterning on the external surfaces of the pair of vibrating arms 10 and 11 respectively, in an electrically isolated condition. Specifically, the first exciting electrode 13 is mainly formed in the groove 18 of the one vibrating arm 10 and on both side surfaces of the other vibrating arm 11, and the second exciting electrode 14 is mainly formed on both side surfaces of the one vibrating arm 10 and in the groove 18 of the other vibrating arm 11. Also, the first exciting electrode 13 and second exciting electrode 14 are electrically connected to the mount electrodes 16 and 17, via the drawing electrodes 19 and 20 respectively, on both main surfaces of the base portion 12.

Also, the weight metal film 21 for carrying out an adjustment (frequency adjustment) of vibration condition of the pair of vibrating arms 10 and 11 in such a way as to vibrate within a predetermined frequency range is formed at the leading ends thereof. The weight metal film 21 is divided into rough adjustment films 21a, used when roughly adjusting the frequency, and fine adjustment films 21b, used when finely adjusting. By carrying out an adjustment of the frequency utilizing the rough adjustment films 21a and fine adjustment films 21b, it is possible to keep the frequency of the pair of vibrating arms 10 and 11 within the nominal frequency range of a device.

### Piezoelectric Vibrator

As shown in FIGS. 1, 3 and 4, the lid substrate 3 is an anodically bondable substrate formed from a glass material, for example, soda-lime glass, and is formed in an approximate plate shape. A recessed portion 3a for the cavity C that houses the piezoelectric vibrating piece 4 is formed in the surface of the lid substrate 3 that bonds to the base substrate 2. The recessed portion 3a is a recessed portion for a cavity that becomes the cavity C that houses the piezoelectric vibrating piece 4 when the two substrates 2 and 3 are placed one on top of the other.

A bonding film 35 for an anodic bonding is formed over the whole of the surface of the lid substrate 3 that bonds to the base substrate 2. That is, the bonding film 35 is formed on the peripheral frame region of the recessed portion 3a in addition to the whole of the internal surface of the recessed portion 3a. The bonding film 35 of the embodiment is formed of Si. When the bonding film 35 is formed of Si, it has superior corrosion resistance compared with a case, to be described hereafter, in which the bonding film 35 is formed from a metal such as Al. Consequently, it is possible to further improve the sealing function of the bonding film 35. Then, by the bonding film 35 and base substrate 2 being anodically bonded, as described hereafter, the cavity C is vacuum sealed.

It is also possible that the bonding film 35 is formed from a material (for example, Al) that is anodically bondable, and that may also be activated by a laser irradiation and adsorb peripheral gas (for example, oxygen). In this case, the bonding film 35 also functions as a getter material. However, the Si bonding film 35 of the embodiment is superior from the point of view of corrosion resistance.

The base substrate 2 is a substrate formed from a glass material, for example, soda-lime glass, and is formed in an approximate plate shape with the same external shape as that of the lid substrate 3, as shown in FIGS. 1 to 4.

Then, as shown in FIGS. 2 to 4, a getter material 34 is formed on the first surface U of the base substrate 2 of the embodiment in such a way as to be housed in the cavity C when the piezoelectric vibrator 1 is formed.

The getter material 34, being activated by a laser irradiation and adsorbing peripheral gas, can be formed from a metal such as Al, Cr, Ti, or zirconium (Zr), or an alloy thereof, or the like. In the embodiment, the getter material 34 is formed from a metal material having Cr as a main component.

The getter material 34 is disposed in a position in which a laser irradiation from outside the piezoelectric vibrator 1 is possible. Herein, the bottom surface of the recessed portion 3a in the lid substrate 3 is an unpolished surface (frosted glass form). For this reason, even when irradiating with a laser from the exterior side of the lid substrate 3 via the recessed portion 3a, the laser diffuses, and it is not possible to adjust the focal point of the laser onto the getter material 34. Meanwhile, both surfaces of the base substrate 2 are polished in a through electrode formation step, to be described hereafter, in the condition of a base substrate wafer. For this reason, the laser irradiation is carried out from the exterior side of the base substrate 2 having polished surfaces. Because of this, the laser does not diffuse, and it is possible to adjust the focal point of the laser onto the getter material 34. Then, the getter material 34 is disposed in a position in which it does not overlap external electrodes 38 and 39, to be described hereafter, in a planar view of the base substrate 2.

Furthermore, the getter material 34 is disposed in a position in which it does not overlap the piezoelectric vibrating piece 4, in the planar view of the base substrate 2, when the piezoelectric vibrating piece 4 is mounted on the base substrate 2. In the example shown in the drawings, one pair of the getter material 34 are disposed one each on the outer sides of the pair of vibrating arms 10 and 11 in the width direction of the piezoelectric vibrating piece 4, in the planar view of the base substrate 2.

Also, a pair of through holes 30 and 31 piercing the base substrate 2 in the thickness direction, and through electrodes 32 and 33, are formed in the base substrate 2.

As shown in FIGS. 2 and 3, the through holes 30 and 31 are formed in such a way as to fit inside the cavity C when the piezoelectric vibrator 1 is formed. To describe in more detail, the through holes 30 and 31 of the embodiment are such that the one through hole 30 is formed in a position corresponding to the base portion 12 side of the piezoelectric vibrating piece 4 mounted in a mounting step, to be described hereafter, and the other through hole 31 is formed in a position corresponding to the leading end side of the vibrating arms 10 and 11.

The through electrode 32 is formed of a glass cylindrical body 6 and a conductive member 7 disposed inside the through hole 30, as shown in FIG. 3.

In the embodiment, the cylindrical body 6 is one wherein a paste form glass frit is sintered. Both ends of the cylindrical body 6 are flat, and it is formed to substantially the same thickness as that of the base substrate 2. Then, the conductive material 7 is disposed in the center of the cylindrical body 6 in such a way as to pierce the cylindrical body 6. Then, the cylindrical body 6 is fixed securely to the conductive material 7 and through hole 30.

The cylindrical body 6 and conductive material 7, as well as maintaining the air tightness of the interior of the cavity C by completely blocking the through hole 30, perform a role of making a drawing electrode 36 and an external electrode 38 conductive with each other, to be described hereafter. The through electrode 33 is formed in the same way as the through electrode 32. Also, the relationship of the through electrode 33, a drawing electrode 37, and an external electrode 39 too is the same kind of relationship as that of the through electrode 32, drawing electrode 36, and external electrode 38.

As shown in FIGS. 2 to 4, the pair of drawing electrodes 36 and 37 are patterned on the first surface U side of the base substrate 2. Of the pair of drawing electrodes 36 and 37, the one drawing electrode 36 is formed in such a way as to be positioned directly above the one through electrode 32. Also, the other drawing electrode 37 is formed in such a way as to be positioned directly above the other through electrode 33, after being drawn along the vibrating arms 10 and 11 to the leading end side of the vibrating arms 10 and 11 from a position adjacent to the one drawing electrode 36.

Then, a bump B is formed on each of the pair of drawing electrodes 36 and 37, and the pair of mount electrodes of the piezoelectric vibrating piece 4 are mounted utilizing the bumps B. Because of this, the one mount electrode 16 of the piezoelectric vibrating piece 4 is made conductive with the one through electrode 32 via the one drawing electrode 36, and the other mount electrode 17 is made conductive with the other through electrode 33 via the other drawing electrode 37.

Also, the pair of external electrodes 38 and 39 are formed on the second surface L of the base substrate 2, as shown in FIGS. 1, 3 and 4. The pair of external electrodes 38 and 39 are formed at either end portion in the longitudinal direction of the base substrate 2, and are electrically connected to the pair of through electrodes 32 and 33 respectively.

When the piezoelectric vibrator 1 configured in this way is operated, a predetermined drive voltage is applied to the external electrodes 38 and 39 formed on the base substrate 2. Because of this, as it is possible to apply a voltage to the exciting electrode 15 formed of the first exciting electrode 13 and second electrode 14 of the piezoelectric vibrating piece 4, it is possible to cause the pair of vibrating arms 10 and 11 to vibrate at a predetermined frequency in a direction approaching or moving away from each other. Then, utilizing the vibration of the pair of vibrating arms 10 and 11, it is possible to utilize the piezoelectric vibrator 1 as a time source, a control signal timing source, a reference signal source, or the like.

### Piezoelectric Vibrator Manufacturing Method

Next, a description will be given, while referring to a flowchart, of the manufacturing method of the piezoelectric vibrator.

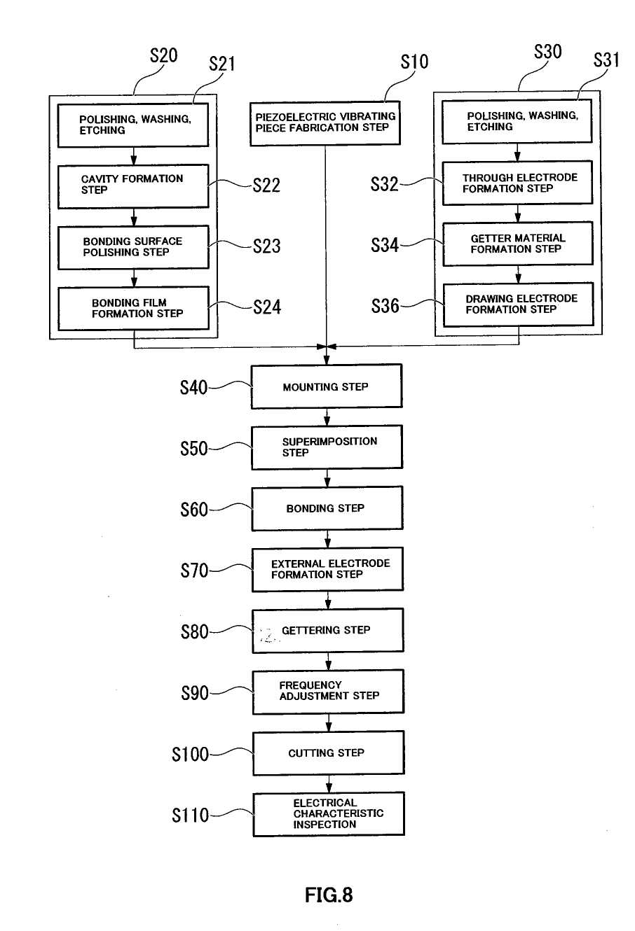

FIG. 8 is a flowchart of the manufacturing method of the piezoelectric vibrator of the embodiment.

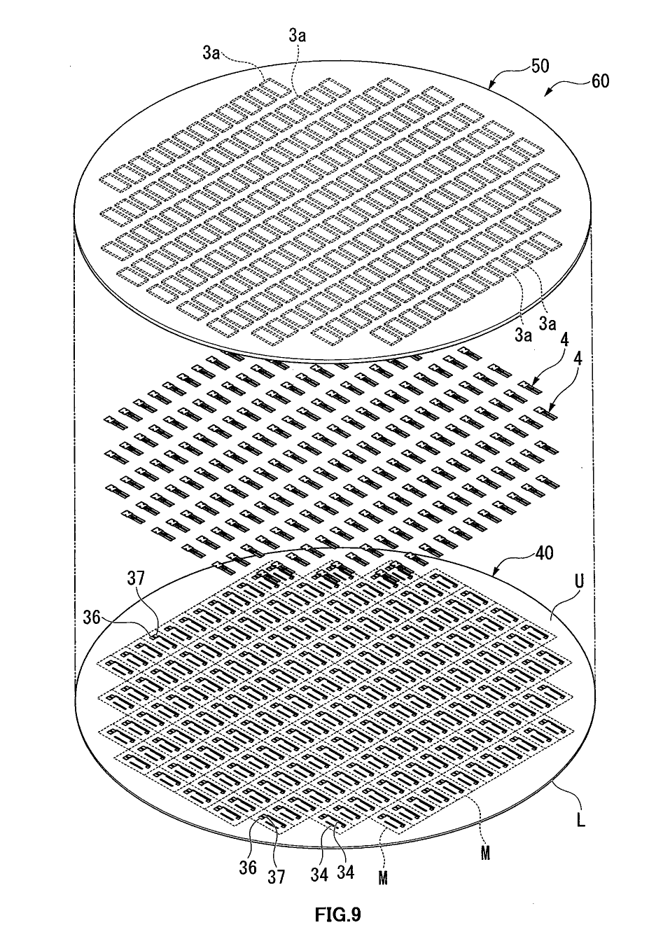

FIG. 9 is an exploded perspective view of a wafer body.

The manufacturing method of the piezoelectric vibrator according to the embodiment mainly includes a piezoelectric vibrating piece fabrication step S10, a lid substrate wafer fabrication step S20, a base substrate wafer fabrication step S30, and an assembly step (from S40 on). Of these, the piezoelectric vibrating piece fabrication step S10, lid substrate wafer fabrication step S20, and base substrate wafer fabrication step S30 can be carried out at the same time.

### Piezoelectric Vibrating Piece Fabrication Step

In the piezoelectric vibrating piece fabrication step S10, the piezoelectric vibrating piece 4 shown in FIGS. 5 to 7 is fabricated. Specifically, firstly, a lumbered quartz raw stone is sliced at a predetermined angle, making a wafer of a certain thickness. Continuing, after a coarse processing of the wafer by lapping, an affected layer is removed by etching, after which a mirror polishing process, such as a polishing, is carried out, making a wafer of a predetermined thickness. Continuing, after an appropriate process, such as a cleaning, is performed on the wafer, the wafer is patterned to the external shape of the piezoelectric vibrating piece 4 using a photolithography technique, and the exciting electrode 15, drawing electrodes 19 and 20, mount electrodes 16 and 17, and weight metal film 21 are formed by carrying out a depositing and patterning of a metal film. By this means, it is possible to fabricate a plurality of piezoelectric vibrating pieces 4. Next, a rough adjustment of the resonance frequency of the piezoelectric vibrating piece 4 is carried out. This is carried out by irradiating the rough adjustment films 21a of the weight metal film 21 with a laser beam, causing one portion thereof to evaporate, and changing the weight of the vibrating arms 10 and 11.

### Lid Substrate Wafer Fabrication Step

In the lid substrate wafer fabrication step S20, a lid substrate wafer 50, which is subsequently to be the lid substrate, is fabricated, as shown in FIG. 9. Firstly, after the disc-shaped lid substrate wafer 50 formed from soda-lime glass is polished to a predetermined thickness and cleaned, the uppermost affected layer is removed by etching, or the like (S21). Next, in a recessed portion formation step S22, a plurality of cavity recessed portions 3a are formed in the surface of the lid substrate wafer 50 that bonds to the base substrate wafer 40. The formation of the recessed portions 3a is carried out using a hot press molding, an etching process, or the like. Next, in a bonding surface polishing step S23, the surface that bonds to the base substrate wafer 40 is polished.

Next, in a bonding film formation step S24, the bonding film 35 shown in FIGS. 1, 2 and 4 is formed on the surface that bonds to the base substrate wafer 40. Normally, it is sufficient that the bonding film 35 is formed on the surface that bonds to the base substrate wafer 40, but in the embodiment, the bonding film 35 is formed over the whole side of the surface of the lid substrate that bonds to the base substrate. Because of this, a patterning of the bonding film 35 is unnecessary, and it is possible to reduce the manufacturing cost. The formation of the bonding film 35 can be carried out using a formation method such as a sputtering or a CVD. As the bonding surface polishing step S23 is carried out before the bonding film formation step S24, the flatness of the surface of the bonding film 35 is ensured, and it is possible to realize a stable bonding with the base substrate wafer 40. At this point, the lid substrate wafer fabrication step S20 finishes.

### Base Substrate Wafer Fabrication Step

In the base substrate wafer fabrication step S30, the base substrate wafer 40, which is subsequently to be the base substrate, is fabricated, as shown in FIG. 9. Firstly, after the disc-shaped base substrate wafer 40 formed from soda-lime glass is polished to a predetermined thickness and cleaned, the uppermost affected layer is removed by etching, or the like (S31).

### Through Electrode Formation Step

Next, a through electrode formation step S32, wherein the pair of through electrodes 32 and 33 are formed in the base substrate wafer 40, is carried out. Hereafter, the formation process of the through electrode 32 will be described, but the formation process of the through electrode 33 is the same.

Firstly, the through hole 30 is shaped from the second surface L to the first surface U of the base substrate wafer 40 by means of a pressing process, or the like. Next, the conductive member 7 is inserted into the through hole 30, and the through hole 30 is filled with a paste material formed from glass frit. Continuing, the paste material is sintered, thus integrating the glass cylindrical body 6, through hole 30, and conductive member 7. Lastly, by polishing the first surface U and second surface L of the base substrate wafer 40, giving the conductive member 7 flat surfaces while exposing it through the first surface U and second surface L, the through electrode 32 is formed inside the through hole 30. By means of the through electrode 32, at the same time as the conductivity of the first surface U side and second surface L side of the base substrate wafer 40 being ensured, it is possible to ensure air tightness inside the cavity C.

### Getter Material Formation Step

Next, a getter material formation step S34, wherein the getter material 34 is formed by patterning an electrically-conductive material on the first surface U side of the base substrate wafer 40, as shown in FIG. 4, is carried out. Either of the getter material formation step S34 and a drawing electrode formation step S36, to be described hereafter, may be carried out first. Furthermore, when the getter material 34 and drawing electrodes 36 and 37 are formed from the same material, the steps may be carried out simultaneously.

In the embodiment, as previously described, the getter material 34 is formed from a metal material having Cr as the main component, and is formed by patterning a Cr layer on the first surface U of the base substrate wafer 40. When the sub-layers of the drawing electrodes 36 and 37 are formed of a Cr layer, it is possible to form the getter material 34 and the sub-layers of the drawing electrodes 36 and 37 at the same time. As shown in FIGS. 2 and 4, the individual pieces of the getter material 34 are formed in such a way as to be disposed opposing each other sandwiching the piezoelectric vibrating piece 4 on either side, in planar view, when the piezoelectric vibrating piece 4 is subsequently mounted on the base substrate wafer 40. Then, the individual pieces of the getter material 34 are formed in such a way as to be adjacent to the vibrating arms 10 and 11 in planar view, and to extend parallel to each other.

### Drawing Electrode Formation Step

Next, returning to FIG. 9, a drawing electrode formation step S36, wherein a plurality of the drawing electrodes 36 and 37 electrically connected to one each of the through electrodes are formed, is carried out. By forming the drawing electrodes 36 and 37 at the same time as the getter material 34, it is possible to manufacture the piezoelectric vibrator 1 more efficiently. Then, bumps of a tapered shape, each formed from gold or the like, are formed on the drawing electrodes 36 and 37. A depiction of the bumps is omitted from FIG. 9 in order to make the drawing easier to understand. At this point, the base substrate wafer fabrication step S30 finishes.

### Mounting Step

Next, a mounting step S40, wherein the piezoelectric vibrating piece 4 is bonded via the bumps B to the drawing electrodes 36 and 37 of the base substrate wafer 40, is carried out. Specifically, the base portion 12 of the piezoelectric vibrating piece 4 is placed on the bumps B, and the piezoelectric vibrating piece 4 is pressed against the bumps B while the bumps B are heated to a predetermined temperature. By this means, the base portion 12 is mechanically fixed to the bumps B in a condition in which the vibrating arms 10 and 11 of the piezoelectric vibrating piece 4 are raised above the first surface U of the base substrate wafer 40, as shown in FIG. 3. Also, the mount electrodes 16 and 17 and drawing electrodes 36 and 37 attain a condition in which they are electrically connected.

### Superimposition Step

After the mounting of the piezoelectric vibrating piece 4 is finished, a superimposition step S50, wherein the lid substrate wafer 50 is superimposed on the base substrate wafer 40 as shown in FIG. 9, is carried out. Specifically, the two wafers 40 and 50 are arrayed in the correct positions while using an unshown reference mark, or the like, as a guide. By this means, the piezoelectric vibrating piece 4 mounted on the base substrate wafer 40 attains a condition in which it is housed in the cavity C enclosed by the recessed portion 3a of the lid substrate wafer 50 and the base substrate wafer 40.

### Bonding Step

After the superimposition step S50, a bonding step S60, wherein the two wafers 40 and 50 laid one on top of the other are put into an unshown anodic bonding device and anodically bonded by applying a predetermined voltage in a predetermined temperature environment, is carried out. Specifically, the predetermined voltage is applied between the bonding film 35 and base substrate wafer 40. Then, an electrochemical reaction takes place at the interface of the bonding film 35 and base substrate wafer 40, the two adhere strongly to each other, and are anodically bonded. Because of this, it is possible to seal the piezoelectric vibrating piece 4 inside the cavity C, and it is possible to obtain a wafer body 60 shown in FIG. 9 wherein the base substrate wafer 40 and lid substrate wafer 50 are bonded. The wafer body 60 is depicted in a disassembled condition in FIG. 9, and a depiction of the bonding film 35 is omitted from the lid substrate wafer 50, in order to make the drawing easier to understand. Dotted lines shown in FIG. 9 depict cutting lines M cut in a subsequently carried out cutting step.

### External Electrode Formation Step

Next, an external electrode formation step S70, wherein a plurality of the pairs of external electrodes 38 and 39 (refer to FIG. 3) electrically connected to the pair of through electrodes 32 and 33 respectively are formed by patterning an electrically-conductive material on the second surface L of the base substrate wafer 40, is carried out. By means of this step, the piezoelectric vibrating piece 4 is continuous with the external electrodes 38 and 39 via the through electrodes 32 and 33.

### Gettering Step

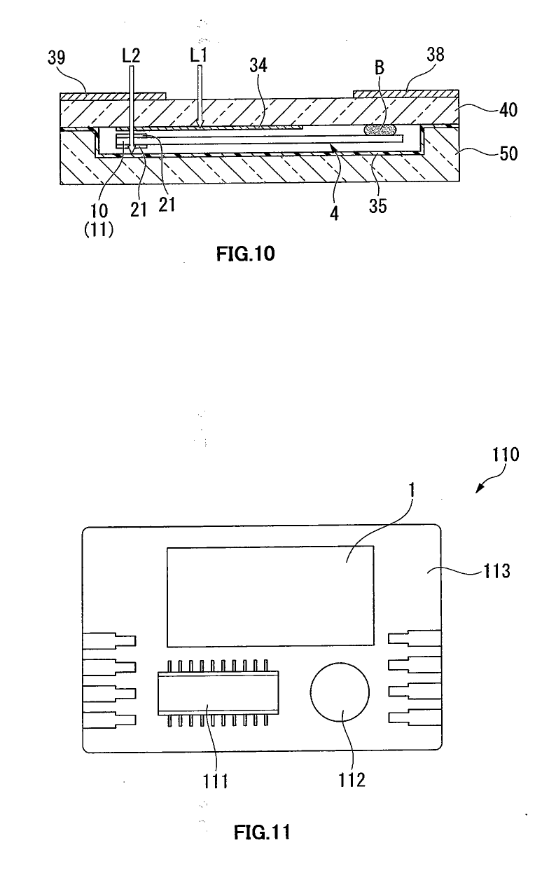

FIG. 10 is an illustration of a gettering step and a frequency adjustment step.

Next, a gettering step S80 wherein, as shown in FIG. 10, the getter material 34 is irradiated with a first laser L1, thus activating the getter material 34 so that it adsorbs gas existing inside the cavity C, is carried out. As the first laser L1, for example, a green laser is employed. The intensity of the first laser L1 will be described hereafter. As heretofore described, as an irradiation with the laser L1 from the exterior side of the lid substrate wafer 50 is not possible, an irradiation with the laser L1 is carried out from the exterior side of the base substrate wafer 40. On irradiating the getter material 34 with the first laser L1, causing the getter material 34 to evaporate, the evaporated getter material 34 absorbs the oxygen inside the cavity C, and generates a metallic oxide. Because of this, as the oxygen inside the cavity C is consumed, it is possible to increase the degree of vacuum inside the cavity C.

As a method of determining an appropriate number of getterings, a method may be employed whereby, for example, a threshold value of a serial vibration resistance value is set in advance for each kind of piezoelectric vibrator, and the number is determined to be appropriate when the resistance value goes below the threshold value. Also, a determination may also be carried out by carrying out a gettering after storing the serial vibration resistance value immediately before the gettering, calculating the rate of change with the serial vibration resistance value immediately after the gettering, and comparing the rate of change with a pre-set value.

### Frequency Adjustment Step

Next, a frequency adjustment step S90 wherein, as shown in FIG. 10, the weight metal film 21 formed at the leading ends of the vibrating arms 10 and 11 of the piezoelectric vibrating piece 4 sealed inside the cavity C is irradiated with a second laser L2, and the frequency of the piezoelectric vibrating piece 4 is finely adjusted, is carried out. In the same way as for the first laser L1, a green laser is employed as the second laser L2. The intensity of the second laser L2 will be described hereafter.

As a specific procedure of the frequency adjustment step S90, firstly, a predetermined voltage is continuously applied from the external electrodes 38 and 39, and the frequency is measured while causing the piezoelectric vibrating piece 4 to vibrate. Next, in this condition, an irradiation with the second laser is carried out from the exterior of the base substrate wafer 40, as shown in FIG. 10, and the fine adjustment films 21b (refer to FIG. 5) of the weight metal film 21 shown in FIGS. 5 and 6 are caused to evaporate. Because of this, as the weight of the leading end sides of the pair of vibrating arms 10 and 11 is reduced, the frequency of the piezoelectric vibrating piece 4 increases. By this means, it is possible to finely adjust the frequency of the piezoelectric vibrator, keeping it within the range of the nominal frequency.

### First Laser and Second Laser Intensities

The intensity of the first laser L1 in the gettering step S80 is set to be weaker than the intensity of the second laser L2 in the frequency adjustment step S90. For example, the intensity of the first laser L1 is set at around 90 percent of the intensity of the second laser L2. The reason is as follows.

The intensity of the second laser L2 in the frequency adjustment step S90 is set so that it is possible to carry out an irradiation that passes through the weight metal film 21 of the piezoelectric vibrating piece 4, as shown in FIG. 10. By carrying out an irradiation with the second laser L2 that passes through the weight metal film 21, it is possible to cause the fine adjustment film of the weight metal film 21 to evaporate without leaving any thermal energy in the piezoelectric vibrating piece. Herein, there is a danger of the second laser L2 reaching the bonding film 35, and the bonding film 35 being dispersed. However, in the frequency adjustment step S90, as the trimming amount of the weight metal film 21 is extremely small, the amount by which the bonding film 35 is trimmed is extremely small even in the event that the second laser L2 reaches the bonding film 35. Then, even in the event that the dispersed bonding film 35 adheres to the vibrating arms 10 and 11 of the piezoelectric vibrating piece 4, as it is of a light weight, there is no effect on the serial vibration resistance value of the piezoelectric vibrator 1.

Meanwhile, in the gettering step S80, when the first laser L1 is set to an intensity equivalent to that of the second laser L2, there is a danger of the first laser L1 penetrating the getter material 34 and piezoelectric vibrating piece 4 and reaching the bonding film 35 formed on the lid substrate wafer 50, and of the bonding film 35 being dispersed. Herein, as the trimming amount of the gettering step S80 is large at approximately five times that of the trimming amount of the frequency adjustment step S90, when the first laser L1 reaches the bonding film 35, a large amount of the bonding film 35 is trimmed. Then, in the event that the dispersed bonding film 35 adheres to the vibrating arms 10 and 11 of the piezoelectric vibrating piece 4, the serial vibration resistance value of the piezoelectric vibrator 1 deteriorates due to the weight of the dispersed bonding film 35.

When the bonding film 35 is formed from Al or the like, the degree of vacuum inside the cavity C increases due to the gettering effect of the bonding film 35. As a result of this, there is a possibility of the serial vibration resistance value of the piezoelectric vibrator 1 improving. However, when the bonding film 35 is formed from Si, as in the embodiment, the bonding film 35 has no gettering effect, meaning that it does not happen either that the serial vibration resistance value of the piezoelectric vibrator 1 improves. Because of this, when the bonding film 35 is formed from Si, there is a considerable need to curb the dispersion of the bonding film.

For the above reason, in the gettering step S80, the intensity of the first laser L1 is set to be lower than the intensity of the second laser L2 so that, even supposing that the first laser L1 reaches the bonding film 35, the amount of the bonding film 35 dispersing is small. Because of this, as it is possible to reduce the amount of the bonding film 35 adhering to the vibrating arms 10 and 11 of the piezoelectric vibrating piece 4, it is possible to prevent the equivalent resistance value of the piezoelectric vibrator 1 from rising.

Furthermore, in the embodiment, the intensity of the first laser L1 is set to be lower than the intensity of the second laser L2, and so that the first laser L1 does not penetrate the getter material 34. Because of this, it does not happen that the first laser L1 reaches the bonding film 35, and it does not happen either that the bonding film 35 disperses. Consequently, as it does not happen either that the bonding film 35 adheres to the vibrating arms 10 and 11 of the piezoelectric vibrating piece 4, it is possible to reliably prevent the equivalent resistance value of the piezoelectric vibrator 1 from rising.

In the embodiment, the laser intensity is adjusted using the same laser emitting device (not shown) in the gettering step S80 and frequency adjustment step S90. Because of this, as it is possible to use the laser emitting device for both the gettering step S80 and frequency adjustment step S90, it is possible to prevent a rise in the manufacturing cost.

### Cutting Step

After the fine adjustment of the frequency is finished, a cutting step S100, wherein the bonded wafer body 60 is cut along the cutting lines M shown in FIG. 9, is carried out. Specifically, firstly, a UV tape is affixed to the surface of the base substrate wafer 40 of the wafer body 60. Next, an irradiation (a scribing) with a laser along the cutting lines M is carried out from the lid substrate wafer 50 side. Next, a cutting blade is pressed along the cutting lines M from the surface of the UV tape, and the wafer body 60 is broken up (a breaking). Subsequently, the UV tape is peeled off by irradiating with a UV. By this means, it is possible to divide the wafer body 60 into a plurality of piezoelectric vibrators. The wafer body 60 may also be cut using another method, such as a dicing.

A step order wherein the frequency adjustment step S90 is carried out after dividing into individual piezoelectric vibrators by carrying out the cutting step S100 is also acceptable. However, as heretofore described, by carrying out the frequency adjustment step S90 first, it is possible to carry out the fine adjustment in the condition of the wafer body 60, meaning that it is possible to more efficiently finely adjust the plurality of piezoelectric vibrators. Therefore, this is preferable as it is possible to achieve an increase in throughput.

### Electrical Characteristic Inspection

Subsequently, an internal electrical characteristic inspection S110 is carried out. That is, the resonance frequency, resonance resistance value, drive level characteristics (the excitation power dependence of the resonance frequency and resonance resistance value), and the like, of the piezoelectric vibrating piece 4 are measured and checked. Also, the insulation resistance characteristics, and the like, are checked at the same time. Then, lastly, an external appearance inspection of the piezoelectric vibrator is carried out, and the dimensions, quality, and the like, are checked for the last time. When this is done, the manufacture of the piezoelectric vibrator is finished.

According to the embodiment, in the gettering step S80, as the intensity of the first laser L1 is lower than the intensity of the second laser L2, as shown in FIG. 10, the amount of the bonding film 35 dispersing is small even in the event that the first laser L1 penetrates the getter material 34 and reaches the bonding film 35 formed on the lid substrate 3. Because of this, as it is possible to reduce the amount of the bonding film 35 adhering to the vibrating arms 10 and 11 of the piezoelectric vibrating piece 4, it is possible to prevent the equivalent resistance value of the piezoelectric vibrator 1 from rising. Consequently, it is possible to prevent the efficiency of the piezoelectric vibrator 1 from deteriorating, and it is possible to manufacture a piezoelectric vibrator 1 with which good electrical characteristics can be obtained.

### Oscillator

Next, a description will be given, while referring to FIG. 11, of one embodiment of an oscillator according to the invention.

An oscillator 110 of the embodiment is configured as a resonator wherein the piezoelectric vibrator 1 is electrically connected to an integrated circuit 111, as shown in FIG. 11. The oscillator 110 includes a substrate 113 on which is mounted an electronic element part 112, such as a capacitor. The oscillator integrated circuit 111 is mounted on the substrate 113, and the piezoelectric vibrating piece of the piezoelectric vibrator 1 is mounted in the vicinity of the integrated circuit 111. The electronic element part 112, integrated circuit 111, and piezoelectric vibrator 1 are electrically connected to each other by an unshown wiring pattern. Each component part is molded from an unshown resin.

In the oscillator 110 configured in this way, when a voltage is applied to the piezoelectric vibrator 1, the piezoelectric vibrating piece in the piezoelectric vibrator 1 vibrates. This vibration is converted into an electrical signal by the piezoelectric characteristics held by the piezoelectric vibrating piece, and input as the electrical signal into the integrated circuit 111. Various kinds of process are performed on the input electrical signal by the integrated circuit 111, and it is output as a frequency signal. By this means, the piezoelectric vibrator 1 functions as the resonator.

Also, for example, by selectively setting a real time clock (RTC) module, or the like, as the configuration of the integrated circuit 111 in accordance with demand, as well as a timepiece single-function oscillator, or the like, it is possible to add functions that control an operating day and time of the instrument or an external instrument, or provide a time, calendar, or the like.

According to the oscillator 110 of the embodiment, as it includes the piezoelectric vibrator 1 manufactured using a manufacturing method with which good electrical characteristics can be obtained, it is possible to provide an oscillator 110 with good performance.

### Electronic Device

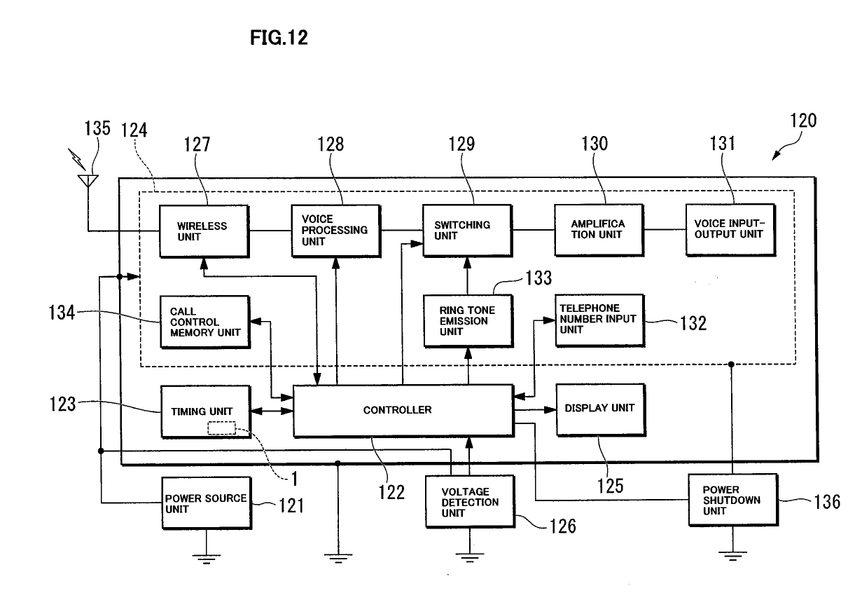

Next, a description will be given, referring to FIG. 12, of one embodiment of an electronic device according to the invention. The description will be given with a portable information instrument 120 having the piezoelectric vibrator 1 as an example of the electronic device. Firstly, the portable information instrument 120 of the embodiment is represented by, for example, a portable telephone, and is a development and improvement of a wristwatch of a heretofore known technology. The external appearance is similar to that of a wristwatch, a liquid crystal display is disposed in a portion corresponding to a dial, and it is possible to display the current time, or the like, on the screen. Also, when utilized as a communication instrument, it is possible to remove the instrument from the wrist, and carry out the same kind of communication as with a portable telephone of a heretofore known technology using a speaker and microphone built into an inner side portion of the strap. However, in comparison with the heretofore known portable telephone, it is markedly smaller and lighter.

Next, a description will be given of the configuration of the portable information instrument 120 of the embodiment. The portable information instrument 120, as shown in FIG. 12, includes the piezoelectric vibrator 1, and a power source unit 121 for supplying power. The power source unit 121 is configured of, for example, a lithium secondary battery. A controller 122 that carries out various kinds of control, a timing unit 123 that carries out a counting of time, or the like, a communication unit 124 that carries out communication with the exterior, a display unit 125 that displays various kinds of information, and a voltage detection unit 126 that detects the voltage of each functional unit, are connected in parallel to the power source unit 121. Then, power is supplied to each functional unit by the power source unit 121.

The controller 122, controlling each functional unit, carries out operational controls of the whole system, such as a transmission and reception of voice data, a measurement of the current time, and a display. Also, the controller 122 includes an ROM into which a program is written in advance, a CPU that reads and executes the program written into the ROM, an RAM used as a work area of the CPU, and the like.

The timing unit 123 includes an integrated circuit incorporating an oscillator circuit, a register circuit, a counter circuit, an interface circuit, and the like, and the piezoelectric vibrator 1. When a voltage is applied to the piezoelectric vibrator 1, the piezoelectric vibrating piece vibrates, and the vibration is converted into an electrical signal by the piezoelectric characteristics held by the quartz, and input as the electrical signal into the oscillator circuit. The output of the oscillator circuit is binarized, and counted by the register circuit and counter circuit. Then, a transmission and reception of a signal is carried out with the controller 122 via the interface circuit, and the current time, the current date, or calendar information, and the like, is displayed in the display unit 125.

The communication unit 124 has the same kinds of function as the heretofore known portable telephone, and includes a wireless unit 127, a voice processing unit 128, a switching unit 129, an amplification unit 130, a voice input-output unit 131, a telephone number input unit 132, a ring tone emission unit 133, and a call control memory unit 134.

The wireless unit 127 carries out a transmission and reception of various kinds of data, such as voice data, with a base station via an antenna 135. The voice processing unit 128 encodes and decodes a voice signal input from the wireless unit 127 or amplification unit 130. The amplification unit 130 amplifies a signal input from the voice processing unit 128 or voice input-output unit 131 to a predetermined level. The voice input-output unit 131, being configured of a speaker, a microphone, and the like, amplifies the ring tone or a received voice, and collects the sound of a voice.

Also, the ring tone emission unit 133 generates a ring tone in response to a call from the base station. By the switching unit 129, only at a time of an incoming call, switching the amplification unit 130 connected to the voice processing unit 128 to the ring tone emission unit 133, the ring tone generated in the ring tone emission unit 133 is output to the voice input-output unit 131 via the amplification unit 130.

The call control memory unit 134 stores a communication program relating to incoming and outgoing call control. Also, the telephone number input unit 132 includes, for example, number keys from 0 to 9 and other keys, and the telephone number or the like of a call destination is input by the number keys and the like being depressed.

When the voltage applied to each functional unit, such as the controller 122, by the power source unit 121 goes below a predetermined value, the voltage detection unit 126 detects the voltage drop, and notifies the controller 122. The predetermined voltage value at this time, being a value set in advance as a minimum voltage needed in order to stably operate the communication unit 124, is, for example, around 3V. The controller 122, on receiving the notification of the voltage drop from the voltage detection unit 126, prohibits the operation of the wireless unit 127, voice processing unit 128, switching unit 129, and ring tone emission unit 133. In particular, stopping the operation of the wireless unit 127, which has a high power consumption, is essential. Furthermore, the fact that the communication unit 124 has become unusable due to an insufficient battery level is displayed in the display unit 125.

That is, it is possible to prohibit the operation of the communication unit 124 with the voltage detection unit 126 and controller 122, and display the fact in the display unit 125. Although the display may be a written message, it is also acceptable, as a more intuitive display, to apply a x (cross) sign to a telephone icon displayed in the upper portion of the display screen of the display unit 125.

By including a power shutdown unit 136 that can selectively shut down the power of portions relating to the functions of the communication unit 124, it is possible to more reliably stop the functions of the communication unit 124.

According to the portable information instrument 120 of the embodiment, as it includes the piezoelectric vibrator 1 manufactured using a manufacturing method with which good electrical characteristics can be obtained, it is possible to provide a portable information instrument 120 with good performance.

### Atomic Timepiece

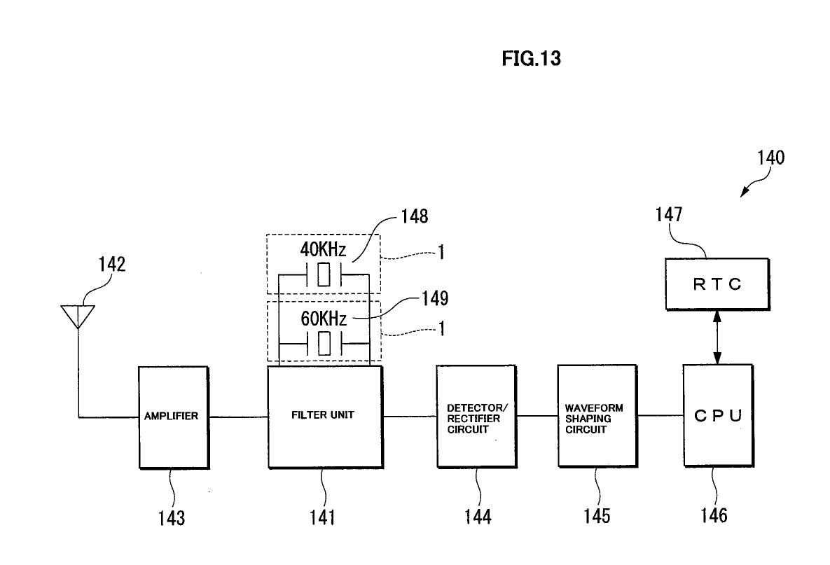

Next, a description will be given, referring to FIG. 13, of one embodiment of an atomic timepiece according to the invention.

An atomic timepiece 140 of the embodiment, including the piezoelectric vibrator 1 electrically connected to a filter unit 141, as shown in FIG. 13, is a clock including functions of receiving a time calibration signal including clock information, automatically correcting the time to the correct time, and displaying the correct time.

Within Japan, there are transmission sites (transmission stations) that transmit time calibration signals in Fukushima Prefecture (40 kHz) and Saga Prefecture (60 kHz), each of which transmits a time calibration signal. As a long wave such as one of 40 kHz or 60 kHz combines a property of being transmitted along the earth's surface and a property of being transmitted while being reflected between the ionosphere and the earth's surface, the transmission range is wide, and the two previously mentioned transmission sites cover the whole of Japan.

Hereafter, a detailed description will be given of a functional configuration of the atomic timepiece 140.

An antenna 142 receives a long wave time calibration signal of 40 kHz or 60 kHz. The long wave time calibration signal is such that time information called a time code is AM modulated into a carrier wave of 40 kHz or 60 kHz. The received long wave time calibration signal is amplified by an amplifier 143, and filtered and tuned by the filter unit 141 having a plurality of the piezoelectric vibrators 1.

The piezoelectric vibrator 1 in the embodiment includes each of quartz vibrator units 148 and 149 having resonance frequencies the same as the carrier frequencies of 40 kHz and 60 kHz.

Furthermore, a filtered signal of a predetermined frequency is detected and demodulated by a detector/rectifier circuit 144.

Continuing, the time code is extracted via a waveform shaping circuit 145, and counted in a CPU 146. Information such as the current year, accumulated days, the day of the week, and the time is read in the CPU 146. The information read is reflected in an RTC 148, and correct time information is displayed.

As the carrier wave is of 40 kHz or 60 kHz, it is preferable that the quartz vibrator units 148 and 149 are vibrators having the tuning-fork shaped structure.

The description given above shows an example from within Japan, but the frequency of the long wave time calibration signal differs overseas. For example, in Germany, a time calibration signal of 77.5 kHz is used. Consequently, when incorporating an atomic timepiece 140 that can also function overseas into the portable instrument, there is a further need for a piezoelectric vibrator 1 of a frequency differing from that when used in Japan.

According to the atomic timepiece 140 of the embodiment, as it includes the piezoelectric vibrator 1 manufactured using a manufacturing method with which good electrical characteristics can be obtained, it is possible to provide an atomic timepiece 140 with good performance.

The invention is not limited to the heretofore described embodiments.

In the embodiments, a description of the manufacturing method is given citing an example of a piezoelectric vibrator using a tuning fork-shaped piezoelectric vibrating piece. However, the manufacturing method of the embodiments may also be employed for a piezoelectric vibrator using, for example, an AT cut type of piezoelectric vibrating piece (a thickness-shear vibrating piece).

In the embodiments, the getter material and the bonding film are formed from differing materials—the getter material being formed from Cr and the bonding film being formed from Si—but both may be formed from the same material. However, as the corrosion resistance improves when the bonding film is formed from Si, the embodiments are superior.

In the embodiments, a green laser (wavelength 532 nm) is employed as the first laser and second laser. However, a laser of a different wavelength may be employed. However, the green laser of the embodiments is superior in that it is excellent for microfabrication.

In the embodiments, the irradiation with the first laser in the gettering step and with the second laser in the frequency adjustment step is carried out using the same laser emitting device. However, the first laser and second laser may be emitted from separate laser emitting devices. By having separate laser emitting devices, there is no longer a need to adjust the laser intensities of the first laser and second laser. Consequently, it is possible to reduce manufacturing man-hours. However, from the point of view of the manufacturing facility cost, the embodiments, wherein the laser emitting device is shared, are superior.

What is claimed is:

1. A method for producing piezoelectric vibrators, comprising:
(a) defining a plurality of first substrates on a first wafer and a plurality of second substrates on a second wafer;
(b) forming a getter material on a respective at least some of the first or second substrates;
(c) layering the first and second wafers such that at least some of the first substrates substantially coincide respectively with at least some of the corresponding second substrates, wherein a piezoelectric vibrating reed having an adjustable weight formed thereon is secured in a respective pairs of at least some of coinciding first and second substrates, and at least some of the pairs include the getter material inside;
(d) anodically bonding the first and second substrates of at least some of the pairs via a bonding film patterned between the first and second substrates;
(e) irradiating a laser with a first power from outside to the getter material in a respective at least some of the anodically bonded pairs to heat the getter material to vacuum the at least some of the anodically bonded pairs; and
(f) irradiating a laser with a second power from outside to the adjustable weight in a respective at least some of the anodically bonded pairs to partially remove the adjustable weight to adjust a frequency of the piezoelectric vibrating reed, wherein the first power is lower than the second power.

2. The method according to claim 1, further comprising, after step (f), cutting off each of at least some of the anodically bonded pairs from the first and second wafers.

3. The method according to claim 1, wherein the bonding film is patterned on an entire inner surface of the first or second substrate.

4. The method according to claim 1, wherein the bonding film is made of Si.

5. The method according to claim 1, wherein forming a getter material comprises placing the getter material in positions to avoid overlapping with the piezoelectric vibrating reed in a plane view

6. The method according to claim 1, wherein at least one of the first and second substrates is substantially translucent to the laser.

7. The method according to claim 3, wherein the getter material mainly includes Cr.

8. The method according to claim 1, wherein steps (e) and (f) are repeated respectively more than one time.

9. The method according to claim 1, wherein irradiating a laser to the getter material comprises:
(g) detecting a serial resonance resistance value of the piezoelectric vibrating reed;
(h) irradiating the later to the getter material; and
(i) repeating step (h) until the serial resonance resistance value becomes below a predetermined value.

10. The method according to claim 1, wherein irradiating a laser to the adjustable weight
(j) detecting the frequency of the vibrating piezoelectric vibrating reed;
(k) irradiating the later to the adjustable weight; and
(l) repeating step (k) until the frequency is properly adjusted.

11. A piezoelectric vibrator comprising:
a hermetically closed casing comprising first and second substrates with a cavity therebetween, at least one of which is translucent to a laser and which are anodically bonded via a bonding film patterned on an entire inner surface of the first or second substrates;
a piezoelectric vibrating reed secured inside the cavity and having an adjustable weight formed thereon; and
at least one getter material attached to an interior surface of the cavity at a place directly irradiatable with a laser from outside of the casing.

12. An oscillator comprising the piezoelectric vibrator defined in claim 11.

13. An electronic device comprising the piezoelectric vibrator defined in claim 11.

14. The electronic device according to claim 13, wherein the electronic device is a real-time clock having the piezoelectric vibrator in a filter.
